(19) United States
(12) Patent Application Publication
(10) Pub. No.: US 2018/0135177 A1
(43) Pub. Date: May 17, 2018

(54) GAS INJECTION APPARATUS AND SUBSTRATE TREATING APPARATUS INCLUDING THE SAME

(71) Applicant: SAMSUNG ELECTRONICS CO., LTD., Suwon-si (KR)

(72) Inventors: JongCheol LEE, Seoul (KR); Jaechul SHIN, Suwon-si (KR); MinHwa JUNG, Suwon-si (KR); Sukjin CHUNG, Hwaseong-si (KR); Geunkyu CHOI, Hwaseong-si (KR); Jung Hwan LEE, Pyeongtaek-si (KR)

(21) Appl. No.: 15/659,940

(22) Filed: Jul. 26, 2017

(30) Foreign Application Priority Data
Nov. 11, 2016 (KR) 10-2016-0150561

(51) Int. Cl. C23C 16/455; C23C 16/458; H01L 21/687

(52) U.S. Cl. CPC C23C 16/45565; H01L 21/68771; C23C 16/458

(57) ABSTRACT

A gas injection apparatus injecting process gases toward a substrate includes a base part, a first gas injection part on the base part, the first gas injection part to inject a first gas including a reaction-inhibiting functional group, a second gas injection part spaced apart from the first gas injection part in one direction on the base part, the second gas injection part to inject a second gas including a precursor of a specific material, and a third gas injection part spaced apart from the second gas injection part in the one direction on the base part, the third gas injection part to inject a third gas reacting with the precursor of the specific material.

### CROSS-REFERENCE TO RELATED APPLICATION

Korean Patent Application No. 10-2016-0150561, filed on Nov. 11, 2016, in the Korean Intellectual Property Office, and entitled: “Gas Injection Apparatus and Substrate Treating Apparatus Including the Same,” is incorporated by reference herein in its entirety.

### BACKGROUND

### 1. Field

Embodiments relate to a gas injection apparatus and a substrate treating apparatus including the same.

### 2. Description of the Related Art

Generally, a plurality of processes (e.g., a deposition process, a photolithography process, a cleaning process, etc.) may be performed to manufacture a semiconductor device. The deposition process among these processes may be a process of forming a material layer on a substrate. A chemical vapor deposition (CVD) process or an atomic layer deposition (ALD) process may be used as the deposition process.

### SUMMARY

Embodiments provide a gas injection apparatus capable of preventing a precursor of a specific material from being over-adsorbed on a local area and a substrate treating apparatus including the same.

In an aspect, a gas injection apparatus injecting process gases toward a substrate may include a base part, a first gas injection part disposed on the base part and injecting a first gas including a reaction-inhibiting functional group, a second gas injection part spaced apart from the first gas injection part in one direction on the base part and injecting a second gas including a precursor of a specific material, and a third gas injection part spaced apart from the second gas injection part in the one direction on the base part and injecting a third gas reacting with the precursor of the specific material.

In an aspect, a gas injection apparatus may include a base part having a circular shape, and a plurality of gas injection parts disposed on the base part and arranged in a circumferential direction of the base part. The plurality of gas injection parts may inject process gases toward a substrate. The gas injection parts may include a source gas injection part injecting a source gas including a precursor of a specific material, a reactive gas injection part facing the source gas injection part and injecting a reactive gas reacting with the precursor of the specific material, and a chemical gas injection part spaced apart from the source gas injection part and the reactive gas injection part between a side of the source gas injection part and a side of the reactive gas injection part. The chemical gas injection part may inject a chemical gas including a reaction-inhibiting functional group.

In an aspect, a substrate treating apparatus may include a reaction chamber, a susceptor rotationally driven in the reaction chamber and supporting at least one substrate, and a shower head disposed over the susceptor in the reaction chamber. The shower head may include a plurality of gas injection parts arranged in a rotational direction of the susceptor and injecting process gases toward a substrate. The plurality of gas injection parts may include a first gas injection part injecting a first gas including a reaction-inhibiting functional group, a second gas injection part spaced apart from the first gas injection part in the rotational direction and injecting a second gas including a precursor of a specific material, and a third gas injection part spaced apart from the second gas injection part in the rotational direction and injecting a third gas reacting with the precursor of the specific material.

In an aspect, a substrate treating apparatus may include a reaction chamber, a susceptor disposed in the reaction chamber and supporting at least one substrate, and a shower head disposed over the susceptor in the reaction chamber. The shower head may sequentially inject a first gas including a reaction-inhibiting functional group, a second gas including a precursor of a specific material, and a third gas reacting with the precursor of the specific material toward a substrate.

In an aspect, a gas injection apparatus may include a base part, a first gas injection part on the base part, the first gas injection part to inject a first gas including a reaction-inhibiting functional group, a second gas injection part on the base part, the second gas injection part being operable only after the first gas injection part to inject a second gas including a precursor of a specific material, and a third gas injection part spaced apart from the second gas injection part in the one direction on the base part, the third gas injection part to inject a third gas reacting with the precursor of the specific material.

### BRIEF DESCRIPTION OF THE DRAWINGS

Features will become apparent to those of ordinary skill in the art by describing in detail exemplary embodiments with reference to the attached drawings, in which:

FIG. 1 illustrates a plan view of a substrate treating apparatus according to some embodiments.

FIG. 2 illustrates a schematic sectional view of the substrate treating apparatus of FIG. 1.

FIG. 3 illustrates a plan view of a gas injection apparatus of FIGS. 1 and 2.

FIG. 4 illustrates a bottom view of the gas injection apparatus of FIGS. 1 and 2.

FIG. 5 illustrates a cross-sectional view taken along a line I-I′ of FIG. 1.

FIG. 6A illustrates a plan view of a susceptor of FIG. 2.

FIG. 6B illustrates a cross-sectional view taken along a line I-I′ of FIG. 6A.

FIG. 7 illustrates a plan view of a modified example of the substrate treating apparatus of FIG. 1.

FIG. 8 illustrates a cross-sectional view taken along a line I-I′ of FIG. 7.

FIG. 9 illustrates a schematic view of a modified example of the substrate treating apparatus of FIG. 1.

FIG. 10 illustrates a flow chart of a method of forming an oxide layer on a substrate by using the substrate treating apparatus of FIG. 1.

FIGS. 11A to 11F illustrate cross-sectional views of stages in a method of forming an oxide layer on a substrate by using the substrate treating apparatus of FIG. 1.

### DETAILED DESCRIPTION

Embodiments will be described hereinafter in detail with reference to the accompanying drawings.

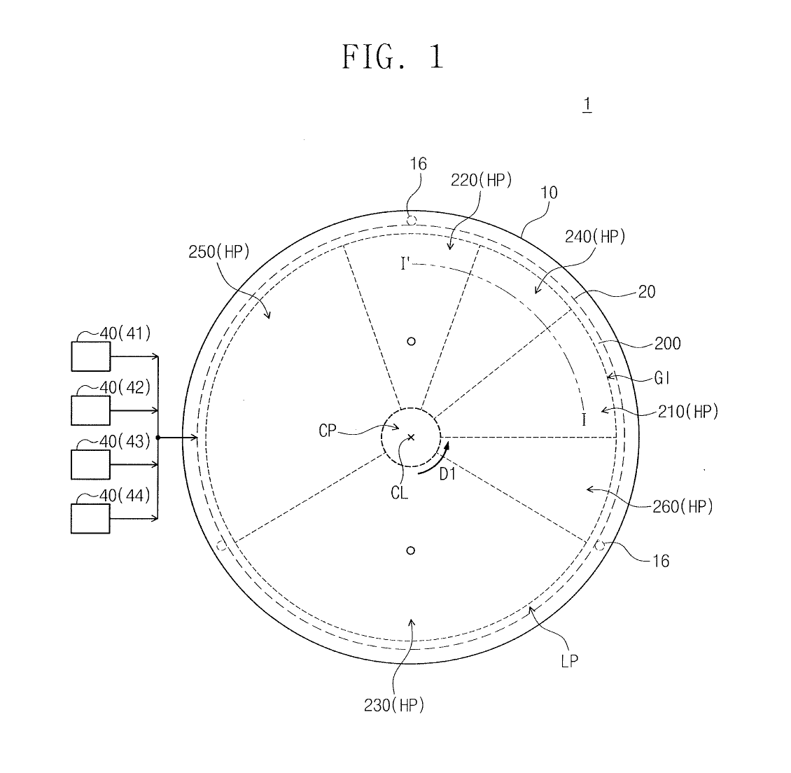

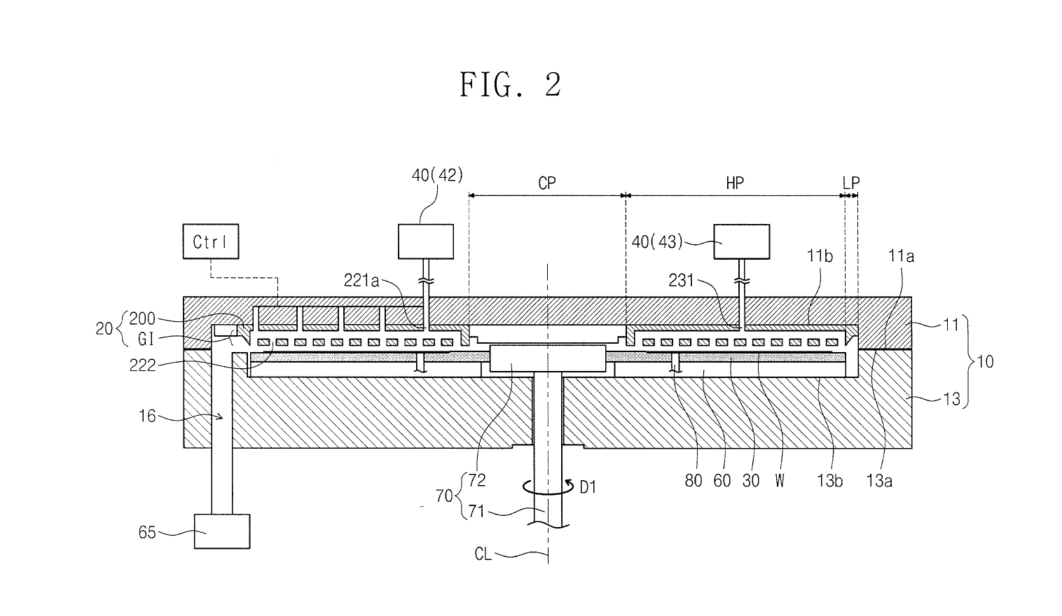

FIG. 1 is a plan view illustrating a substrate treating apparatus according to some embodiments. FIG. 2 is a cross-sectional schematic view illustrating the substrate treating apparatus of FIG. 1.

Referring to FIGS. 1 and 2, a substrate treating apparatus 1 may include a reaction chamber 10, a susceptor 30, and a gas injection apparatus 20. The substrate treating apparatus 1 may further include gas supply parts 40 and a gas exhaust unit 65. The substrate treating apparatus 1 may supply a process gas to substrates W to perform a process on the substrates W. For example, the substrate treating apparatus 1 may perform a process of depositing a thin layer on the substrates W. In some embodiments, the substrate treating apparatus 1 may be an atomic layer deposition (ALD) apparatus. For example, the substrate treating apparatus 1 may be a space-division type ALD apparatus. The substrates W may be, but not limited to, semiconductor wafers.

The reaction chamber 10 may provide an inner space in which the process is performed on the substrates W. The inner space of the reaction chamber 10 may be sealed from the outside. The reaction chamber 10 may include an upper housing 11 and a lower housing 13. The upper and lower housings 11 and 13 may have, but not limited to, a circular container shape. The upper housing 11 and the lower housing 13 may be detachably coupled to each other. For example, the upper housing 11 may vertically move to be separated from and/or coupled to the lower housing 13. For example, as illustrated in FIG. 2, while edges 11 a and 13a of the upper and lower housings 11 and 13 may contact each other, the inner space may be defined between facing surfaces 11b and 13b of the upper and lower housings 11 and 13 to accommodate the susceptor 30 and the gas injection apparatus 20.

The gas injection apparatus 20 may be disposed in the reaction chamber 10. The gas injection apparatus 20 may be vertically spaced apart from a top surface of the susceptor 30 in the reaction chamber 10, e.g., the gas injection apparatus 20 may be between the surface 11b of the upper housing 11 and the susceptor 30 in the reaction chamber 10. The gas injection apparatus 20 may inject or provide various process gases toward the substrates W supported on the susceptor 30, e.g., the gas injection apparatus 20 may be a shower head.

The gas injection apparatus 20 may include a central region CP, high-pressure regions HP, and a low-pressure region LP. The central region CP may be disposed at a central region of the gas injection apparatus 20, e.g., to overlap a shaft. The high-pressure regions HP may be connected to, e.g., extend radially from, the central region CP, e.g., to overlap portions of the susceptor 30 supporting the substrates W. The high-pressure regions HP may be gas injection regions in which the process gas is provided toward the substrates W. The high-pressure regions HP may be in a low-vacuum state of about 10 mTorr to about 100 mTorr. The high-pressure regions HP may be disposed in fan shapes with respect to the central region CP, e.g., the high-pressure regions HP may be arranged adjacent to each other along a perimeter of the central region CP (FIG. 1). The low-pressure region LP may surround, e.g., an entire perimeter of, the high-pressure regions HP. The low-pressure region LP may be a gas exhaust region through which the process gas is exhausted. The low-pressure region LP may be in a high-vacuum state of about 1 mTorr to about 10 mTorr. The low-pressure region LP may be connected to gas exhaust ports 16 of the reaction chamber 10.

The gas injection apparatus 20 may include a base part 200 and a plurality of gas injection parts GI.

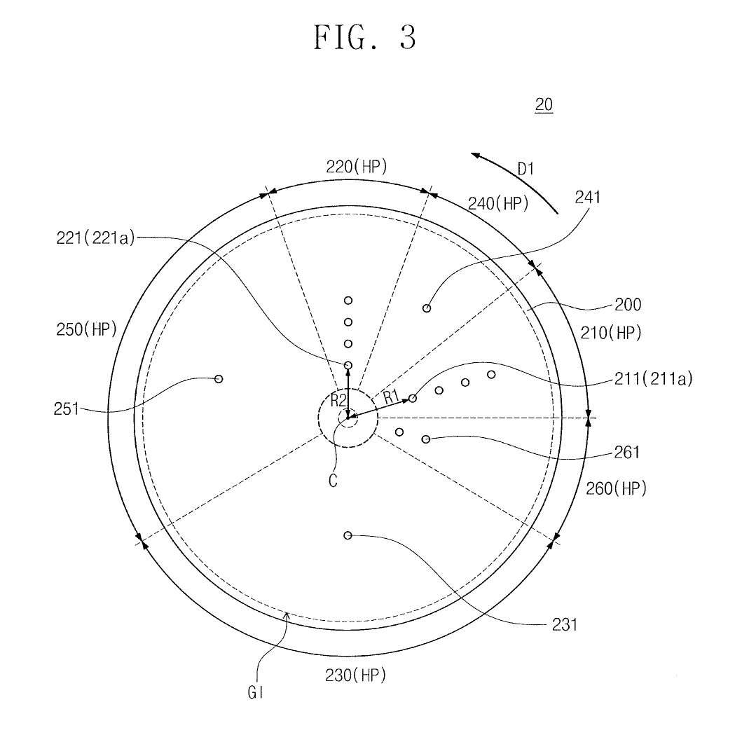

The base part 200 may be disposed to face the susceptor 30. For example, a bottom surface of the base part 200 may be disposed to face the top surface of the susceptor 30. For example, the gas injection parts GI may be positioned between the base part 200 and the susceptor 30, so the gas injection parts GI may inject or provide the process gas to the substrates W supported on the susceptor 30. The plurality of gas injection parts GI may be the aforementioned high-pressure regions HP of the gas injection apparatus 20. The gas injection parts GI may be arranged along one direction D1. For example, the one direction D1 may be a counterclockwise direction. However, embodiments are not limited thereto. In certain embodiments, the one direction D1 may be a clockwise direction or a linear direction. This will be described later in more detail with reference to FIGS. 3, 4, and 5.

The gas supply parts 40 may supply various process gases to the gas injection apparatus 20. For example, as illustrated in FIG. 2. the gas supply parts 40 may be connected to corresponding ones of the gas injection parts GI through the base part 200 to supply the various process gases, as will be described later in detail.

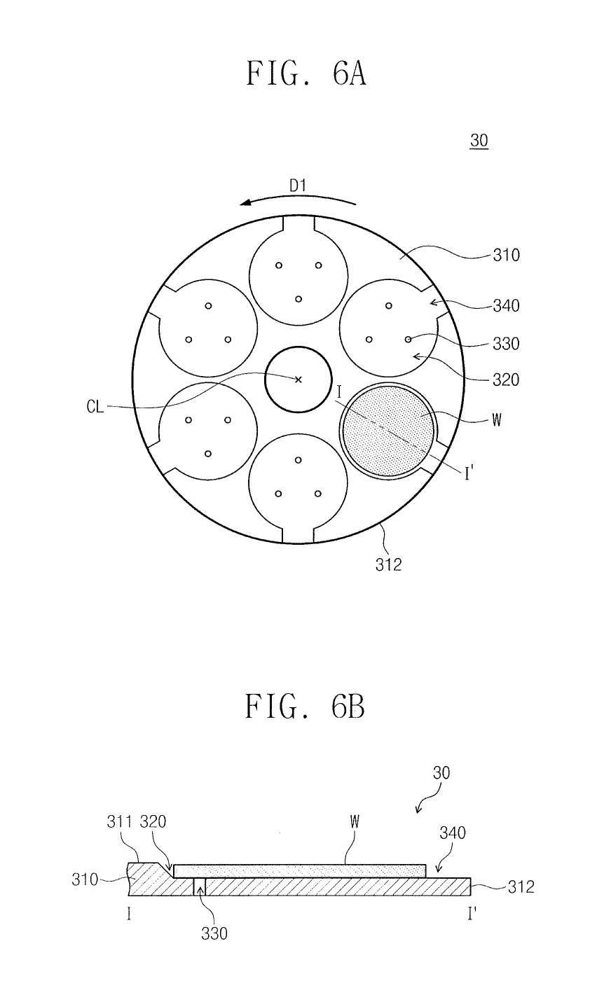

The susceptor 30 may be disposed in the reaction chamber 10. The susceptor 30 may support the substrates W. The substrates W supported on the susceptor 30 may be separated from the susceptor 30 by lift pins 80 which penetrate the susceptor 30 and ascend, e.g., the lift pins 80 may move vertically through pin holes in the susceptor 30 to lift the substrates W from the susceptor 30, as will be described in more detail below with reference to FIGS. 6A-6B.

A rotation driving unit 70 may be connected to a central region of the susceptor 30, e.g., to overlap the central region CP. The rotation driving unit 70 may include a rotation shaft 71, a rotation driving part (not shown) driving the rotation shaft 71, and a holder 72 connecting the rotation shaft 71 to the susceptor 30. The holder 72 may be disposed at the central region of the susceptor 30. One end of the rotation shaft 71 may be connected to the holder 72. Another end of the rotation shaft 71 may be connected to the rotation driving part (e.g., a motor). The rotation shaft 71 may be parallel to an imaginary center line CL of the gas injection apparatus 20, e.g., the imaginary center line CL may be a rotation axis of the rotation shaft 71. The susceptor 30 may be rotationally driven by the rotation driving unit 70 in the reaction chamber 10. A rotational direction of the susceptor 30 may be the same as the one direction D1. For example, the rotational direction of the susceptor 30 may be a counterclockwise direction or a clockwise direction. When the susceptor 30 is rotationally driven, e.g., around the imaginary center line CL, the substrates W may be sequentially located under each of the, e.g., corresponding, gas injection parts GI. The susceptor 30 may be smaller than the gas injection apparatus 20, e.g., the susceptor 30 may have a smaller diameter than the gas injection apparatus 20. The susceptor 30 will be described later in more detail with reference to FIGS. 6A and 6B.

A heater part 60 may be disposed in the inner space between the surface 13b of the lower housing 13 and the susceptor 30. The heater part 60 may be fixed on the lower housing 13. The heater part 60 may generate heat by external power to heat the susceptor 30 and the substrates W.

The gas exhaust unit 65 may be connected to the reaction chamber 10. In more detail, the gas exhaust unit 65 may be connected to the gas exhaust port 16 of the lower housing 13. The gas exhaust unit 65 may exhaust the process gas remaining in the reaction chamber 10 to the outside of the reaction chamber 10 through the gas exhaust port 16. The gas exhaust unit 65 may be, but not limited to, a vacuum pump.

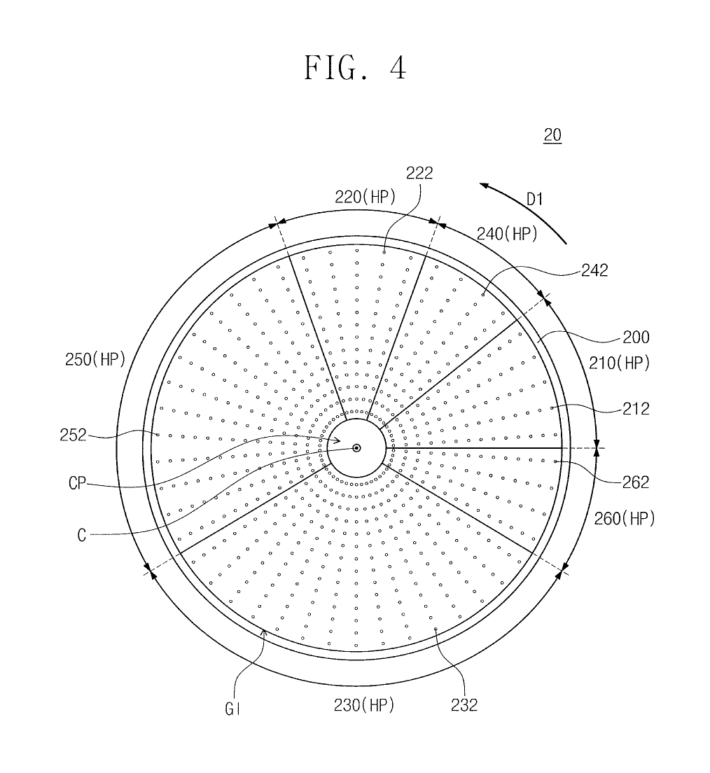

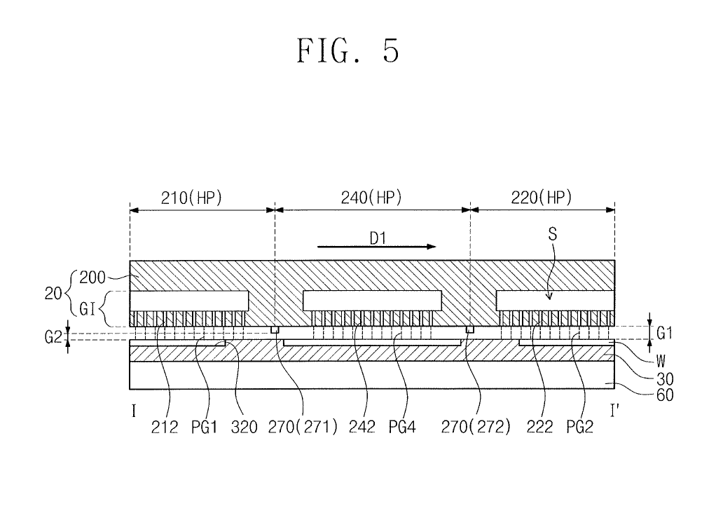

FIG. 3 is a plan view illustrating the gas injection apparatus 20. FIG. 4 is a bottom view illustrating the gas injection apparatus 20. FIG. 5 is a cross-sectional view taken along line I-I′ of FIG. 1.

Referring to FIGS. 1, 3, 4, and 5, the base part 200 of the gas injection apparatus 20 may have a, e.g., circular, shape. The base part 200 may have at least one inlet 211, 221, 231, 241, 251, or 261 in an overlapping region with each of the gas injection parts GI, e.g., each of the inlets 211, 221, 231, 241, 251, or 261 may correspond to a separate gas injection part GI (regions separated by dashed lines in FIG. 3) and extend through the base 200 to provide gas into the corresponding gas injection part GI. The inlets 211, 221, 231, 241, 251, and 261 may be connected to the gas supply parts 40. This will be described later in more detail.

As illustrated in FIG. 5, the plurality of gas injection parts GI may be disposed on the base part 200. For example, the plurality of gas injection parts GI may protrude from the bottom surface of the base part 200 toward the susceptor 30. The one direction may be a circumferential direction of the base part 200.

As further illustrated in FIG. 5, the base part 200 and each of the gas injection parts GI may form a space S in which the injected process gas is diffused. As illustrated in FIGS. 4-5, each of the gas injection parts GI may include a plurality of nozzles 212, 222, 232, 242, 252, or 262 connected to the space S. The process gases may be injected or provided toward the substrates W through the plurality of nozzles 212, 222, 232, 242, 252, and 262 adjacent to the susceptor 30. This will be described later in detail.

As illustrated in FIGS. 3-4, each of the gas injection parts GI may extend in a radial direction from a center of the base part 200. A width of each of the gas injection parts GI in the one direction D1 may become progressively greater in the radial direction. In other words, each of the gas injection parts UI may have a fan shape. In some embodiments, the imaginary center line CL described above may pass through the center of the base part 200. The gas injection parts GI may include a chemical gas injection part 210, a source gas injection part 220, a reactive gas injection part 230, and a plurality of purge gas injection parts 240, 250, and 260.

The chemical gas injection part 210 (hereinafter, referred to as ‘a first gas injection part 210’) may inject or provide a chemical gas PG1 (hereinafter, referred to as ‘a first gas PG1’) including a reaction-inhibiting functional group toward the substrates W. The first gas PG1 may be a compound including the reaction-inhibiting functional group.

The reaction-inhibiting functional group may include at least one of an alkoxy group having a carbon number of 1 to 4, an aryloxy group having a carbon number of 6 to 10, an ester group having a carbon number of 1 to 5, or an arylester group having a carbon number of 7 to 10. In some embodiments, the reaction-inhibiting functional group may be obtained by chemisorbing (or chemically adsorbing) any compound including the reaction-inhibiting functional group to surfaces of the substrates W. The compound including the reaction-inhibiting functional group may be, e.g., methanol (CH₃OH), ethanol (C₂H₅OH), propanol (C₃H₇OH), butanol (C₄H₉OH), formic acid (HCOOH), acetic acid (CH₃COOH), propanoic acid (C₂H₅COOH), butanoic acid (C₃H₇COOH), pentanoic acid (C₄H₉COOH), phenol (C₆H₅OH), or benzoic acid (C₆H₅COOH).

The source gas injection part 220 (hereinafter, referred to as ‘a second gas injection part 220’) may be spaced apart from the first gas injection part 210 in the one direction D1. Since the rotational direction of the susceptor 30 of FIG. 2 is the same as the one direction D1 as described above, a second gas to be described below may be supplied onto the substrate W through the second gas injection part 220 after the first gas PG1 is supplied onto the substrate W.

The second gas injection part 220 may be spaced apart from the first gas injection part 210 by a first angle with respect to a central axis. The first angle may range from about 30 degrees to about 60 degrees. The second gas injection part 220 may inject or provide a source gas PG2 (hereinafter, referred to as ‘a second gas PG2’) including a precursor of a specific material toward the substrates W. The specific material may be a metal and/or a semiconductor material.

The second gas PG2 may include a silicon precursor and/or a metal precursor including at least one of, but not limited to, aluminum (Al), titanium (Ti), zirconium (Zr), hafnium (Hf), vanadium (V), tantalum (Ta), niobium (Nb), scandium (Sc), yttrium (Y), lutetium (Lu), calcium (Ca), strontium (Sr), barium (Ba), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), or ytterbium (Yb). In some embodiments, the precursor of the specific material and the compound including the reaction-inhibiting functional group may be in a liquid state. The compound and the precursor of the specific material in the liquid state may be evaporated into a gaseous state by an evaporator and may be injected into the first and second gas injection parts 210 and 220.

An overlapping area of the second gas injection part 220 and the base part 200 may be greater than an overlapping area of the first gas injection part 210 and the base part 200. Thus, the amount of the second gas PG2 injected or provided to the substrates W may be larger than the amount of the first gas PG1 injected or provided to the substrates W.

The reactive gas injection part 230 (hereinafter, referred to as ‘a third gas injection part 230’) may be spaced apart from the second gas injection part 220 in the one direction D1. The third gas injection part 230 may face the second gas injection part 220 with the central region CP of the gas injection apparatus 20 interposed therebetween. The third gas injection part 230 may be spaced apart from the second gas injection part 220 by a second angle with respect to the central axis. The second angle may range from about 90 degrees to about 160 degrees. An overlapping area of the third gas injection part 230 and the base part 200 may be greater than an overlapping area of the second gas injection part 220 and the base part 200. Thus, the amount of a reactive gas injected or provided to the substrates W may be larger than the amount of the second gas PG2 injected or provided to the substrates W.

The third gas injection part 230 may inject or provide the reactive gas (hereinafter, referred to as ‘a third gas’) reacting with the precursor of the specific material. An oxidation reaction may occur between the reactive gas and the precursor of the specific material. Thus, the reactive gas may include an oxidizing agent that reacts with the precursor of the specific material to cause the oxidation reaction. The oxidizing agent may include, but not limited to, ozone (O₃), oxygen (O₂), water (H₂O), hydrogen peroxide (H₂O₂), or nitrous oxide (N₂O).

The plurality of purge gas injection parts 240, 250, and 260 may inject or provide a purge gas PS4 toward the substrates W. The number of the purge gas injection parts 240, 250, and 260 may be three. The purge gas may be a non-reactive gas which does not react with the first to third gases. The non-reactive gas may be an inert gas (e.g., argon (Ar), helium (He), or neon (Ne)) or a nitrogen gas. The purge gas injection parts 240, 250, and 260 may purge the first to third gases remaining on the substrates W and may act as fences such that the first to third gases are not mixed with each other.

A first purge gas injection part 240 may be located in front of, e.g., adjacent to, the first gas injection part 210 in the one direction D1. The first purge gas injection part 240 may be disposed between the first and second gas injection parts 210 and 220. The first purge gas injection part 240 may be disposed to be adjacent to the first and second gas injection parts 210 and 220, e.g., so the purge gas in the first purge gas injection part 240 may separate between the first and second gas injection parts 210 and 220.

A second purge gas injection part 250 may be located in front of, e.g., adjacent to, the second gas injection part 220 in the one direction D1. The second purge gas injection part 250 may be disposed between the second and third gas injection parts 220 and 230. The second purge gas injection part 250 may be disposed to be adjacent to the second and third gas injection parts 220 and 230, e.g., so the purge gas in the second purge gas injection part 250 may separate between the second and third gas injection parts 220 and 230.

A third purge gas injection part 260 may be located in front of, e.g., adjacent to, the third gas injection part 230 in the one direction D1. The third purge gas injection part 260 may be disposed between the first and third gas injection parts 210 and 230. The third purge gas injection part 260 may be disposed to be adjacent to the first and third gas injection parts 210 and 230, e.g., so the purge gas in the third purge gas injection part 260 may separate between the first and third gas injection parts 210 and 230.

An injection area, through which the purge gas is injected or provided toward the substrates W, of the second purge gas injection part 250 may be greater than those of the first and third purge gas injection parts 240 and 260. Thus, the amount of the purge gas injected or provided from the second purge gas injection part 250 may be greater than the amount of the purge gas injected or provided from each of the first and third purge gas injection parts 240 and 260. The gas injection apparatus 20 may inject or provide the first to third gases and the purge gas at the same time toward the susceptor 30 and/or the substrates W.

The base part 200 may have a plurality of first inlets 211 in a region vertically overlapping with the first gas injection part 210. The first inlets 211 may be connected to a first gas supply part 41 of FIG. 1 supplying the first gas PG1. Thus, the first gas PG1 of the first gas supply part 41 may be supplied into the first gas injection part 210 through the first inlets 211.

The base part 200 may have a plurality of second inlets 221 in a region vertically overlapping with the second gas injection part 220. The number of the second inlets 221 may be equal to the number of the first inlets 211. The second inlets 221 may be connected to a second gas supply part 42 of FIG. 1 supplying the second gas PG2. Thus, the second gas PG2 of the second gas supply part 42 may be supplied into the second gas injection part 220 through the second inlets 221. The first inlets 211 may be arranged in a first radial direction from the center of the base part 200, and the second inlets 221 may be arranged in a second radial direction from the center of the base part 200. Here, the second radial direction may be different from the first radial direction.

The second inlets 221 may include a second inlet 221a (hereinafter, referred to as ‘an innermost second inlet 221a’) adjacent to the center C of the base part 200, and the first inlets 211 may include a first inlet 211a (hereinafter, referred to as ‘an innermost first inlet 211a’) adjacent to the center C of the base part 200. Here, the innermost second inlet 221a may be closer to the center C of the base part 200 than the innermost first inlet 211a may be. In other words, a first distance R1 between the center C of the base part 200 and the innermost first inlet 211a may be greater than a second distance R2 between the center C of the base part 200 and the innermost second inlet 221a. For example, as illustrated in FIG. 3, the plurality of the first inlets 211 may be arranged adjacent to each other, e.g., at equal distances, along an imaginary extension line of the first distance R1, and the plurality of the second inlets 221 may be arranged adjacent to each other, e.g., at equal distances, along an imaginary extension line of the second distance R2.

The base part 200 may have a third inlet 231 in a region vertically overlapping with the third gas injection part 230, and may have fourth inlets 241, 251, and 261 in regions vertically overlapping with the purge gas injection parts 240, 250, and 260, respectively. The third inlet 231 may be connected to a third gas supply part 43 of FIG. 1 supplying the third gas, and the fourth inlets 241, 251, and 261 may be connected to a fourth gas supply part 44 of FIG. 1 supplying the purge gas PS4.

The central region CP of the gas injection apparatus 20 may be an air curtain region. A very small amount of the purge gas may be provided into the central region CP. The low-pressure region LP of the gas injection apparatus 20 may surround outer sides of the gas injection parts GI which are the high-pressure regions HP.

As illustrated in FIG. 5, the gas injection apparatus 20 may further include a plurality of gas barrier walls 270. Each of the gas barrier walls 270 may be disposed between the gas injection parts GI adjacent to each other. In more detail, each of the gas barrier walls 270 may be disposed at a boundary between the gas injection parts GI adjacent to each other.

The nozzles of the gas injection parts GI may be disposed to be adjacent to the susceptor 30 and/or the substrates W. For example, as illustrated in FIG. 5, the nozzles 212 of the first gas injection part 210, the nozzles 222 of the second gas injection part 220, and the nozzles 242 of the first purge gas injection part 240 may be disposed to be adjacent to the susceptor 30 and/or the substrates W. For example, a first gap G1 may be defined between the susceptor 30 and the nozzles 212 of the first gas injection part 210, between the susceptor 30 and the nozzles 222 of the second gas injection part 220, and between the susceptor 30 and the nozzles 242 of the first purge gas injection part 240. For example, the first gap G1 may be defined between the top surface of the susceptor 30 and bottoms of the nozzles in the gas injection parts GI. The first gap G1 may be about 4 mm.

The precursor of the specific material, e.g., in the second gas PG2, may become more adsorbed on the surfaces of the substrates W when the first gap GI is reduced. However, a space into which the precursor of the specific material is injected may become narrower as the first gap G1 decreases. Thus, the precursor of the specific material may be over-adsorbed on a local area of the substrate. In contrast. according to the aforementioned embodiments, the first gas PG1 may be injected or provided onto the substrates W before the second gas PG2 is injected or provided onto the substrates

W, so the reaction-inhibiting functional group included in the first gas PG1 may be chemisorbed on the substrates W. As a result, when the second gas PG2 is injected or provided to the substrates W, on which the reaction-inhibiting functional group had been previously adsorbed, it is possible to prevent the precursor (e.g., the metal precursor) of the specific material from being over-adsorbed on a local area of the substrate.

The process gas may flow into the low-pressure region LP through the first gap G1.

The gas barrier walls 270 may inhibit the process gas injected from one of the gas injection parts GI from flowing to other gas injection part GI adjacent thereto. For example, a first gas barrier wall 271 between the first gas injection part 210 and the first purge gas injection part 240 may reduce a flow of the first gas PG1 in the one direction D1. A second gas barrier wall 272 between the first purge gas injection part 240 and the second gas injection part 220 may reduce a flow of the purge gas PS4 in the one direction D1. Thus, the first and second gas barrier walls 271 and 272 and the first purge gas injection part 240 may inhibit or prevent the first gas PG1 from flowing to the second gas injection part 220.

A second gap G2 may be disposed, e.g., defined, between the susceptor 30 and, e.g., bottom surfaces of, the gas barrier walls 270. The second gap G2 may be smaller than the first gap G1. The gas barrier walls 270 may extend in radial directions from the center C of the base part 200, e.g., toward the low-pressure region LP.

FIG. 6A is a plan view illustrating the susceptor 30. FIG. 6B is a cross-sectional view taken along line I-I′ of FIG. 6A.

Referring to FIGS. 1, 2, 6A, and 6B, the susceptor 30 may support the substrates W. The susceptor 30 may have a, e.g., circular, plate shape. The susceptor 30 may include a body 310 and at least one insertion recess 320 recessed into the body 310, such that the substrate W is inserted into the insertion recess 320. The insertion recess 320 may be a region recessed downwardly from the top surface 311 of the body 310 of the susceptor 30. The insertion recess 320 may be provided to correspond to the substrate W, e.g., in terms of shape and size. For example, the insertion recess 320 may have a circular shape when the substrate W has a circular shape. The top surface 311 of the susceptor 30 may face the gas injection parts GI described above.

The insertion recess 320 may be provided in plurality. The plurality of insertion recesses 320 may be arranged along the rotational direction of the susceptor 30. The rotational direction of the susceptor 30 may be the same as the one direction D1 described above. The number of the insertion recesses 320 may correspond to the number of the gas injection parts GI of the gas injection apparatus 20, e.g., the number of the insertion recesses 320 may be six.

The susceptor 30 may further include connection recesses 340 extending outwardly from the insertion recesses 320. The connection recesses 340 may connect the insertion recesses 320 to an edge sidewall 312 of the susceptor 30. The process gas in the insertion recesses 320 may be easily exhausted to the outside of the susceptor 30 through the connection recesses 340. The connection recess 340 may be a trench having a bottom surface lower than the top surface 311 of the susceptor 30. A width of the connection recess 340 may be smaller than a width of the insertion recess 320 and/or a width of the substrate W. Thus, the substrate W disposed in the insertion recess 320 may not escape from the susceptor 30 through the connection recess 340.

The susceptor 30 may further include a plurality of pin holes 330 penetrating a bottom surface of the insertion recess 320. When the upper housing 11 is separated from the lower housing 13, the lift pins 80 of FIG. 2 may pass through the pin holes 330 to separate the substrate W from the insertion recess 320. In other words, the lift pins 80 may elevate the substrate W. The elevated substrate W may be transferred to the outside of the reaction chamber 10 of FIG. 2 by a substrate transfer unit.

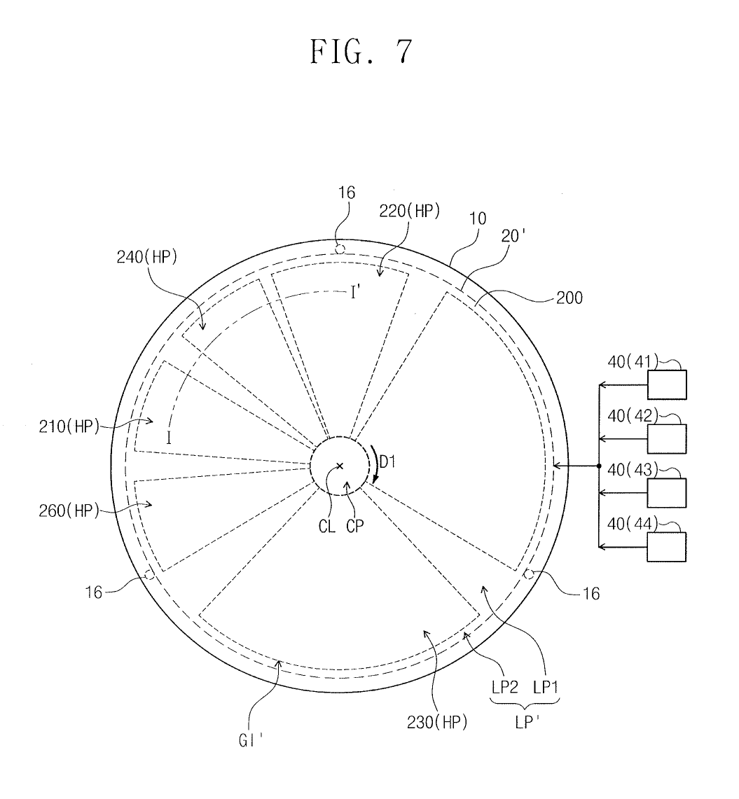

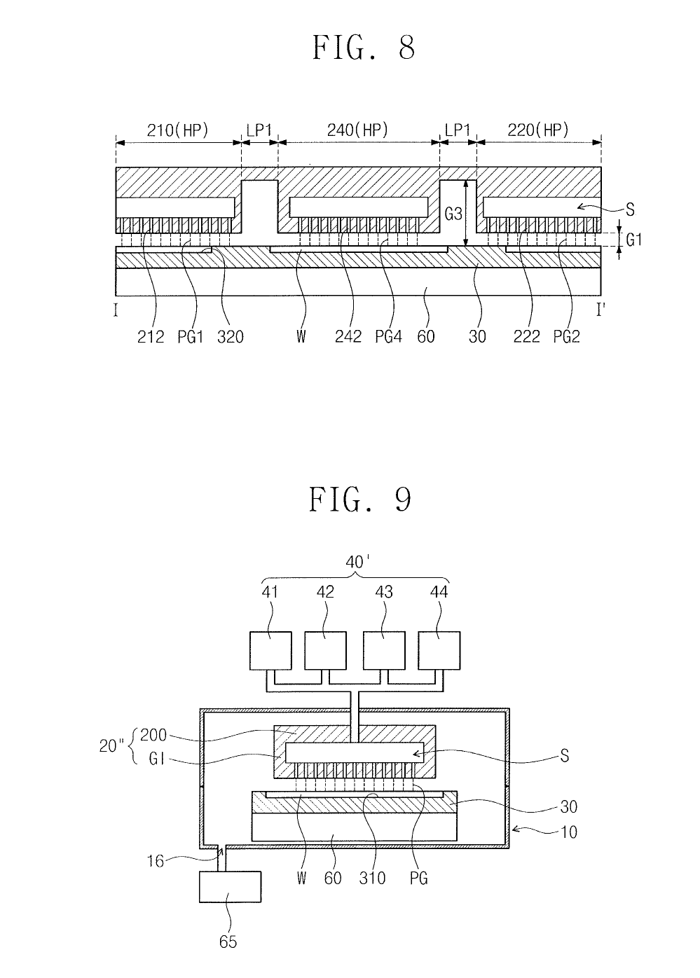

FIG. 7 is a plan view illustrating a modified example of the substrate treating apparatus of FIG. 1. FIG. 8 is a cross-sectional view taken along line I-I′ of FIG. 7. For the purpose of ease and convenience in explanation, the descriptions of the same elements as in the embodiments of FIGS. 1-6B will be omitted or mentioned only briefly.

Referring to FIGS. 7 and 8, gas injection parts GI′ of a gas injection apparatus 20′ according to the present modified embodiment may be spaced apart from each other in the one direction D1, unlike the gas injection parts GI of FIG. 1. In some embodiments, the one direction D1 may be a clockwise direction. In addition, the susceptor 30 and the substrates W may be rotated in the clockwise direction.

A low-pressure region LP′ of the gas injection apparatus 20′ may include an outer low-pressure region LP2 and an inner low-pressure regions LP1. The outer low-pressure region LP2 may surround an outer periphery of the gas injection parts GI′. Each of the inner low-pressure regions LP1 may be disposed between the gas injection parts GI′ adjacent to each other. The inner low-pressure regions LP1 may be connected to the outer low-pressure region LP2. Since each of the inner low-pressure regions LP1 is disposed between the gas injection parts GI adjacent to each other, the process gas injected or provided from the gas injection parts GI may be rapidly exhausted through the inner low-pressure regions LP1.

For example, as illustrated in FIG. 8, the nozzles 212 of the first gas injection part 210, the nozzles 222 of the second gas injection part 220, and the nozzles 242 of the first purge gas injection part 240 may form the first gap GI with the top surface of the susceptor 30. In the inner low-pressure region LP1, the base part 200 of the gas injection apparatus 20′ may form a third gap G3 with the top surface of the susceptor 30. The third gap G3 may be greater than the first gap G1. The third gap G3 may be about 25 mm. The process gas may flow into the outer low-pressure region LP2 through the first and third gaps G1 and G3. The amount of the process gas exhausted through the inner low-pressure region LP2 having the third gap G3 may be more than the amount of the process gas exhausted through the high-pressure region HP having the first gap G1.

FIG. 9 is a schematic view illustrating a modified example of the substrate treating apparatus of FIG. 1. For the purpose of ease and convenience in explanation, the descriptions to the same elements as in the embodiments of FIGS. 1-6B will be omitted or mentioned only briefly. It is noted that the substrate treating apparatus of FIG. 9 is a time-division type ALD apparatus, unlike the substrate treating apparatus 1 of FIG. 1.

Referring to FIG. 9, the substrate treating apparatus may include the reaction chamber 10, a gas injection apparatus 20″, the susceptor 30, gas supply parts 40′, and the gas exhaust unit 65.

The gas injection apparatus 20″ may sequentially inject or provide process gases toward the substrate W disposed on the susceptor 30. The process gases may include the first to third gases and the purge gas, which are described above. For example, the gas injection apparatus 20″ may inject or provide the first gas, the purge gas, the second gas, the purge gas, the third gas, and the purge toward the substrate in the order listed.

The gas injection apparatus 20″ may include the base part 200 and at least one gas injection part GI. In some embodiments, the gas injection apparatus 20″ may include one gas injection part GI. The gas injection part GI may be connected to a plurality of the gas supply parts 40′ through an inlet. The gas injection part GI may be supplied with various process gases from the gas supply parts 40′. For example, the gas injection part GI may be supplied with the first to third gases and the purge gas, which are described above.

The gas injection part GI may inject or provide each of the process gases through nozzles. For example, the gas injection part GI may inject or provide the first gas toward the substrate W. After a certain period of time, the gas injection part GI may inject or provide the purge gas toward the substrate W. After a certain period of time, the gas injection part GI may inject or provide the second gas toward the substrate W. After a certain period of time, the gas injection part GI may inject or provide the purge gas toward the substrate W. After a certain period of time, the gas injection part GI may inject or provide the third gas toward the substrate W. After a certain period of time, the gas injection part GI may inject or provide the purge gas toward the substrate W. Like these, the gas injection apparatus 20″ may provide the first to third gases and the purge gas toward the susceptor 30 and/or the substrate W on the basis of predetermined time intervals.

In the certain period of time, the gas exhaust unit 65 may exhaust the process gas remaining in the reaction chamber 10 through the exhaust port 16.

An operation of the substrate treating apparatus 1 according to the aforementioned embodiments will be described hereinafter.

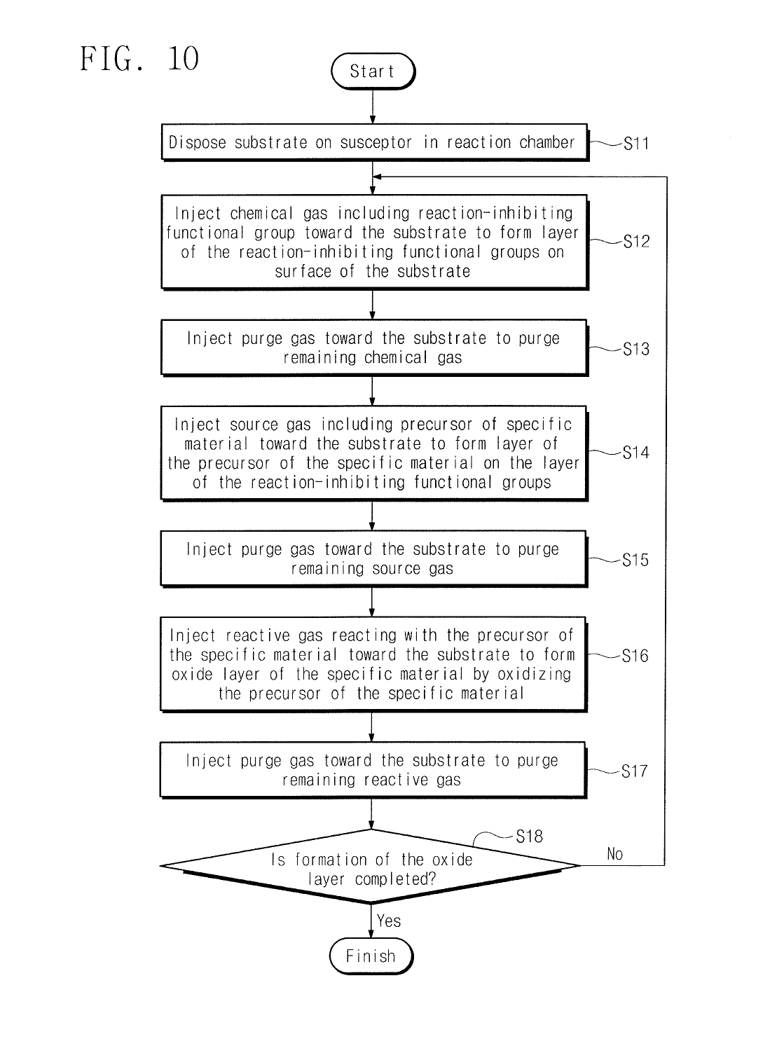

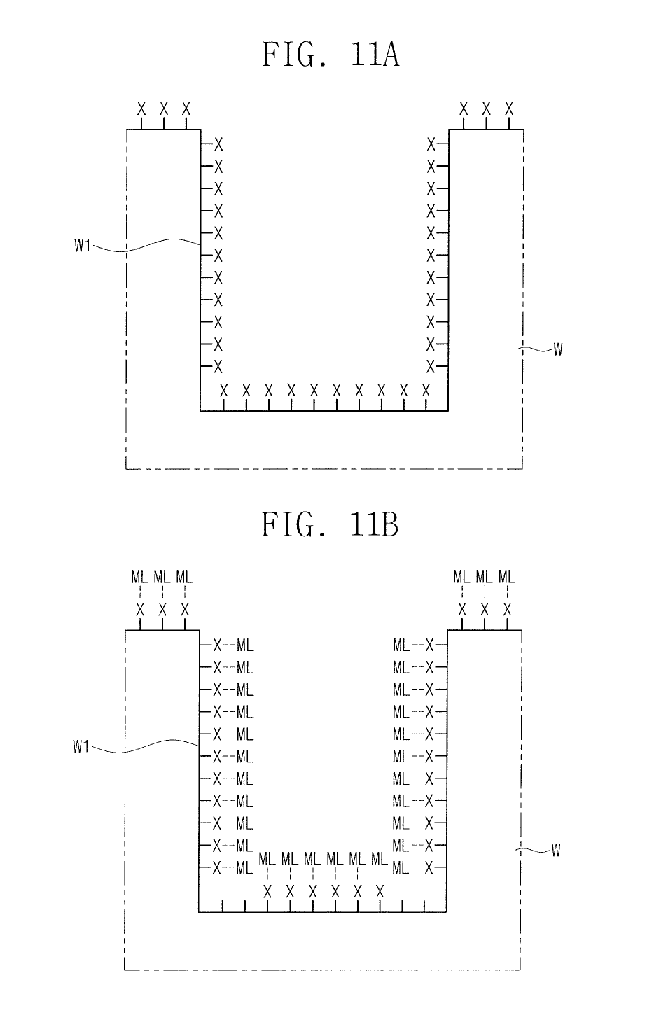

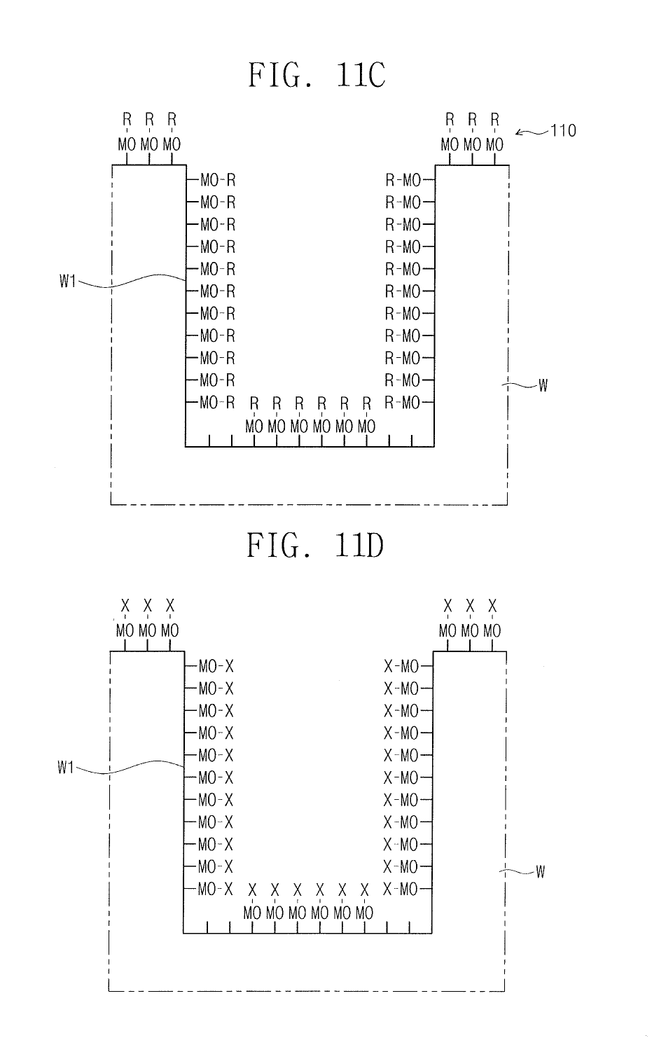

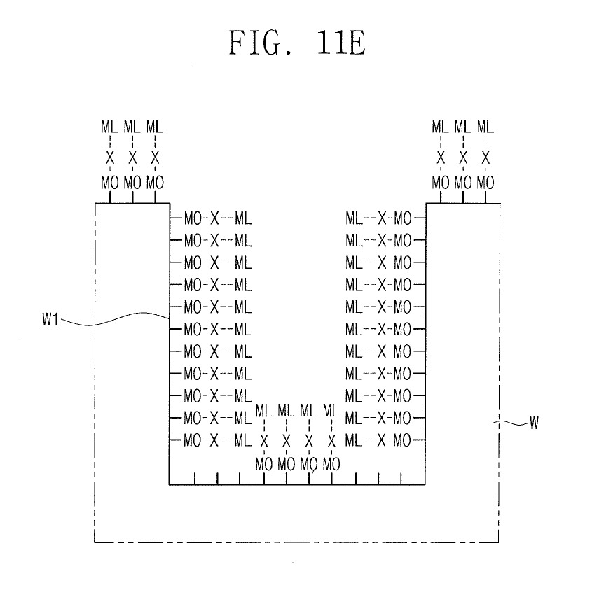

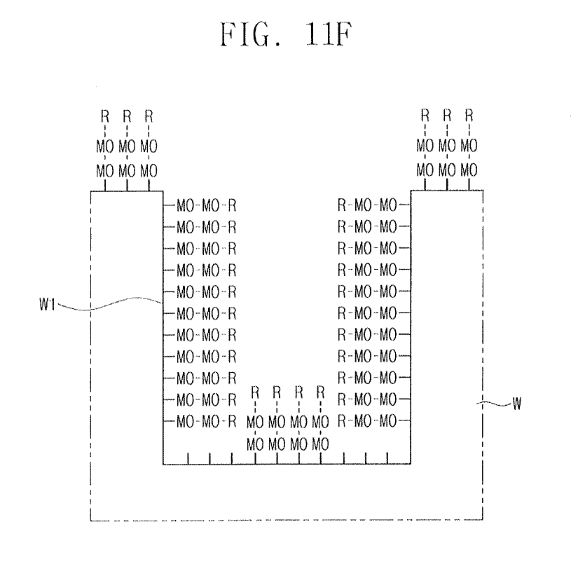

FIG. 10 is a flow chart illustrating a method of forming an oxide layer on a substrate by using the substrate treating apparatus of FIG. 1. FIGS. 11A to 11F are cross-sectional views illustrating stages in a method of forming an oxide layer on the substrate W by using the substrate treating apparatus of FIG. 1.

Referring to FIGS. 10 and 11A, the substrate W may be inserted into the insertion recess 320 of the susceptor 30 (FIG. 6B). The susceptor 30 on which the substrate W is disposed may be disposed in the reaction chamber 10 of FIG. 2. In other words, the substrate W may be disposed on the susceptor 30 in the reaction chamber 10 (S11). In some embodiments, a surface W1 of the substrate W may include a trench having an aspect ratio of 20 or more. The susceptor 30 may be rotated in the one direction D1 to locate, e.g., position, the substrate W under the first gas injection part 210.

The first gas injection part 210 (see FIG. 3) may inject or provide the first gas including the reaction-inhibiting functional groups —X toward the substrate W. The reaction-inhibiting functional groups —X of the first gas may be chemisorbed on the surface W1 of the substrate W. Thus, a layer of the reaction-inhibiting functional groups —X may be formed on the surface W1 of the substrate W (S12).

Alternatively, in certain embodiments, the third gas injection part 230 may inject or provide the third gas including the oxidizing agent toward the substrate W before the layer of the reaction-inhibiting functional groups —X is formed on the surface W1 of the substrate W. The third gas may form a layer of a reaction active element on the surface W1 of the substrate W. The reaction active element may be an atom or functional group, which has an instable bond including oxygen. For example, the reaction active element may be oxygen radical or a hydroxy functional group. The susceptor 30 may be rotated in the one direction D1 to locate the substrate W under the third purge gas injection part 260. The third purge gas injection part 260 may purge the third gas remaining on the surface W1 of the substrate W.

The susceptor 30 may be rotated in the one direction D1 to locate, e.g., position.

the substrate W under the first purge gas injection part 240 of FIG. 3. The first purge gas injection part 240 may inject or provide the purge gas toward the substrate W. The purge gas may purge the first gas remaining on the surface W1 of the substrate W (S13). In more detail, the reaction-inhibiting functional groups —X may form the layer of the reaction-inhibiting functional groups —X on the surface W1 of the substrate W, and a residual compound including the reaction-inhibiting functional groups —X may also be physically adsorbed (or physisorbed) on the substrate W or the layer of the reaction-inhibiting functional groups —X. The purge gas may purge the physisorbed residual compound. Thus, it is possible to prevent the residual compound from unnecessarily reacting with other process gases subsequently provided.

Referring to FIGS. 10 and 11B, the susceptor 30 may be rotated in the one direction D1 to locate, e.g., position, the substrate W under the second gas injection part 220 of FIG. 3. The second gas injection part 220 may inject or provide the second gas including precursor ML of the specific material toward the substrate W, e.g., the second gas injection part 220 may be operable only after the first gas injection part 210 via a controller ctrl (FIG. 2). The precursor ML of the specific material may be physically adsorbed to the reaction-inhibiting functional groups —X to form a layer of the precursor ML of the specific material on the layer of the reaction-inhibiting functional groups —X (S14). Thus, it is possible to prevent the precursor ML of the specific material from being over-adsorbed on the substrate W.

The susceptor 30 may be rotated in the one direction D1 to locate, e.g., position, the substrate W under the second purge gas injection part 250 of FIG. 3. The second purge gas injection part 250 may inject or provide the purge gas toward the substrate W. The purge gas may purge the second gas remaining on the substrate W (S15).

Referring to FIGS. 10 and 11C, the susceptor 30 may be rotated in the one direction D1 to locate, e.g., position, the substrate W under the third gas injection part 230. The third gas injection part 230 (see FIG. 3) may inject or provide the third gas reacting with precursor ML of the specific material toward the substrate W. The third gas may include the oxidizing agent which reacts with the precursor ML of the specific material to cause the oxidation reaction. The third gas may oxidize the layer of the precursor of the specific material to form an oxide layer 110 (S16). The oxide layer 110 may include an oxide MO of the precursor of the specific material.

The oxide MO of the precursor of the specific material may be combined with the reaction active element —R. For example, a surface of the oxide layer 110 may be terminated with the reaction active element —R. The reaction active element —R may include oxygen, oxygen radical, and/or a hydroxy group (—OH). For example, when ozone or oxygen is used as the oxidizing agent, the reaction active element —R may include oxygen or oxygen radical. In some embodiments, when the precursor of the specific material is oxidized, the reaction-inhibiting functional groups —X on which the precursor ML of the specific material is adsorbed may be removed.

The susceptor 30 may be rotated in the one direction D1 to locate, e.g., position, the substrate W under the third purge gas injection part 260 of FIG. 3. The third purge gas injection part 260 may inject or provide the purge gas toward the substrate W. The purge gas may purge the third gas remaining on the substrate W (S17). Thus, one cycle of the deposition process described above may be completed.

Referring to FIG. 10, it may be determined whether formation of the oxide layer 110 is completed or not (S18). For example, whether the formation of the oxide layer 110 is completed or not may be determined in consideration of a material of the oxide layer 110, a thickness of the oxide layer 110, and/or a dielectric constant of the oxide layer 110. The cycle including the processes described above may be further performed one or more times when it is necessary to form an additional oxide layer 110 or increase a thickness of the oxide layer 110, e.g., FIGS. 11D-11F to repeat operations S12 to S17.

According to some embodiments, the compound including a reaction-inhibiting functional group may be supplied to the substrate before the precursor of the specific material is supplied to the substrate. Thus, the precursor of the specific material may be pyrolyzed. As a result, it is possible to prevent the precursor of the specific material from being over-adsorbed on a local area of the substrate.

The methods, processes, and/or operations described herein may be performed, at least partially, by code or instructions to be executed by a computer, processor, controller, or other signal processing device in the substrate treating apparatus of the embodiments. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods described herein.

The controllers and other processing features described herein may be implemented in logic which, for example, may include hardware, software, or both. When implemented at least partially in hardware, the controllers and other processing features may be, for example, any one of a variety of integrated circuits including but not limited to an application-specific integrated circuit, a field-programmable gate array, a combination of logic gates, a system-on-chip, a microprocessor, or another type of processing or control circuit.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A gas injection apparatus injecting process gases toward a substrate, the gas injection apparatus comprising:
a base part;
a first gas injection part on the base part, the first gas injection part to inject a first gas including a reaction-inhibiting functional group;
a second gas injection part spaced apart from the first gas injection part in one direction on the base part, the second gas injection part to inject a second gas including a precursor of a specific material; and
a third gas injection part spaced apart from the second gas injection part in the one direction on the base part, the third gas injection part to inject a third gas reacting with the precursor of the specific material.

2. The gas injection apparatus as claimed in claim 1, further comprising a plurality of purge gas injection parts on the base part to inject a purge gas, the purge gas injection parts including:
a first purge gas injection part between the first and second gas injection parts,
a second purge gas injection part between the second and third gas injection parts, and
a third purge gas injection part in front of the third gas injection part in the one direction.

3. The gas injection apparatus as claimed in claim 2, wherein the one direction is a clockwise direction or a counterclockwise direction.

4. The gas injection apparatus as claimed in claim 3, wherein the third purge gas injection part is between the first and third gas injection parts.

5.-7. (canceled)

8. The gas injection apparatus as claimed in claim 1, wherein:
the base part includes a plurality of first inlets in a region overlapping with the first gas injection part, and a plurality of second inlets in a region overlapping with the second gas injection part,
the first inlets are arranged in a first radial direction from a center of the base part, and
the second inlets are arranged in a second radial direction from the center of the base part, the second radial direction being different from the first radial direction.

9. The gas injection apparatus as claimed in claim 8, wherein a second inlet adjacent to the center of the base part among the second inlets is closer to the center of the base part than a first inlet adjacent to the center of the base part among the first inlets.

10. The gas injection apparatus as claimed in claim 1, wherein:
the specific material is a metal or a semiconductor material, and
the reaction-inhibiting functional group includes at least one of an alkoxy group having a carbon number of 1 to 4, an aryloxy group having a carbon number of 6 to 10, an ester group having a carbon number of 1 to 5, or an arylester group having a carbon number of 7 to 10.

11. The gas injection apparatus as claimed in claim 1, wherein the third gas includes an oxidizing agent that reacts with the precursor of the specific material.

12. A gas injection apparatus, comprising:
a base part having a circular shape; and
a plurality of gas injection parts on the base part to inject process gases toward a substrate, the plurality of gas injection parts being arranged in a circumferential direction of the base part,
wherein the gas injection parts include:
a source gas injection part to inject a source gas including a precursor of a specific material,
a reactive gas injection part facing the source gas injection part, the reactive gas injection part to inject a reactive gas reacting with the precursor of the specific material, and
a chemical gas injection part spaced apart from the source gas injection part and from the reactive gas injection part, the chemical injection part being between a first side of the source gas injection part and a first side of the reactive gas injection part to inject a chemical gas including a reaction-inhibiting functional group.

13. The gas injection apparatus as claimed in claim 12, wherein the gas injection parts further include:
a first purge gas injection part between the chemical gas injection part and the source gas injection part to inject a first purge gas;
a second purge gas injection part between a second side of the source gas injection part and a second side of the reactive gas injection part to inject a second purge gas; and
a third purge gas injection part between the reactive gas injection part and the chemical gas injection part to inject a third purge gas.

14. (canceled)

15. The gas injection apparatus as claimed in claim 12, wherein the base part includes:
a plurality of chemical gas inlets in a region vertically overlapping with the chemical gas injection part, the chemical gas being supplied into the chemical gas injection part through the plurality of chemical gas inlets; and
a plurality of source gas inlets in a region vertically overlapping with the source gas injection part, the source gas being supplied into the source gas injection part through the plurality of source gas inlets,
wherein the chemical gas inlets are arranged in a first radial direction from a center of the base part, and
wherein the source gas inlets are arranged in a second radial direction from the center of the base part, the second radial direction being different from the first radial direction.

16. The gas injection apparatus as claimed in claim 15, wherein a source gas inlet adjacent to the center of the base part among the source gas inlets is closer to the center of the base part than a chemical gas inlet adjacent to the center of the base part among the chemical gas inlets.

17. (canceled)

18. The gas injection apparatus as claimed in claim 12, wherein:
the specific material is a metal or a semiconductor material, and
the reaction-inhibiting functional group includes at least one of an alkoxy group having a carbon number of 1 to 4, an aryloxy group having a carbon number of 6 to 10, an ester group having a carbon number of 1 to 5, or an arylester group having a carbon number of 7 to 10.

19. The gas injection apparatus as claimed in claim 12, wherein the reactive gas includes an oxidizing agent that reacts with the precursor of the specific material.

20. A substrate treating apparatus, comprising:
a reaction chamber;
a susceptor rotationally driven in the reaction chamber, the susceptor supporting at least one substrate; and
a shower head over the susceptor in the reaction chamber, the shower head including a plurality of gas injection parts arranged in a rotational direction of the susceptor to inject process gases toward the at least one substrate, and the plurality of gas injection parts including:
a first gas injection part to inject a first gas including a reaction-inhibiting functional group,
a second gas injection part spaced apart from the first gas injection part in the rotational direction, the second gas injection part to inject a second gas including a precursor of a specific material, and
a third gas injection part spaced apart from the second gas injection part in the rotational direction, the third gas injection part to inject a third gas reacting with the precursor of the specific material.

21. The substrate treating apparatus as claimed in claim 20, wherein the plurality of gas injection parts further include:
a first purge gas injection part between the first and second gas injection parts to inject a first purge gas;
a second purge gas injection part between the second and third gas injection parts to inject a second purge gas; and
a third purge gas injection part between the first and third gas injection parts to inject a third purge gas.

22. The substrate treating apparatus as claimed in claim 20, wherein the first gas injection part faces the second gas injection part.

23. The substrate treating apparatus as claimed in claim 20, wherein the susceptor includes:
a first surface facing the gas injection parts; and
a plurality of insertion recesses on the first surface, a substrate being inserted in each of the insertion recesses, and the insertion recesses being arranged along the rotational direction.

24. The substrate treating apparatus as claimed in claim 20, wherein:
the specific material is a metal or a semiconductor material, and
the reaction-inhibiting functional group includes at least one of an alkoxy group having a carbon number of 1 to 4, an aryloxy group having a carbon number of 6 to 10, an ester group having a carbon number of 1 to 5, or an arylester group having a carbon number of 7 to 10.

25. The substrate treating apparatus as claimed in claim 20, wherein the third gas includes an oxidizing agent that reacts with the precursor of the specific material.

26.-35. (canceled)
